(19) United States
(12) Patent Application Publication
(10) Pub. No.: US 2015/0062826 A1
(43) Pub. Date: Mar. 5, 2015

(54) ELECTRONIC DEVICE WITH HEAT DISSIPATION FUNCTION

(71) Applicant: HON HAI PRECISION INDUSTRY CO., LTD., New Taipei (TW)

(72) Inventor: TAI-WEI LIN, New Taipei (TW)

(73) Assignee: HON HAI PRECISION INDUSTRY CO., LTD., New Taipei (TW)

(21) Appl. No.: 14/056,971

(22) Filed: Oct. 18, 2013

(30) Foreign Application Priority Data
Sep. 5, 2013 (TW) 102132078

(51) Int. Cl. H05K 1/02

(52) U.S. Cl. CPC H05K 1/0203
USPC 361/720

(57) ABSTRACT

An electronic device includes a housing defining an opening, a circuit board mounted in the housing, and a cover capable of conducting heat and covering the opening. An element and a hollow partition portion receiving the element are mounted on the circuit board. The cover includes a block formed on an inner surface of the cover. The block enters the partition portion and contacts the element.

### BACKGROUND

1. Technical Field

The present disclosure relates to an electronic device with heat dissipation function.

2. Description of Related Art

Heat sinks are often mounted on electronic elements to dissipate heat generated by these elements. However, the hot heat sink may heat up the air inside an electronic device receiving the elements, and the heated air cannot be cooled rapidly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device.

FIG. 2 is an assembled, isometric view of FIG. 1.

FIG. 3 is a cross-sectional view of FIG. 2, taken along the line III-III.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

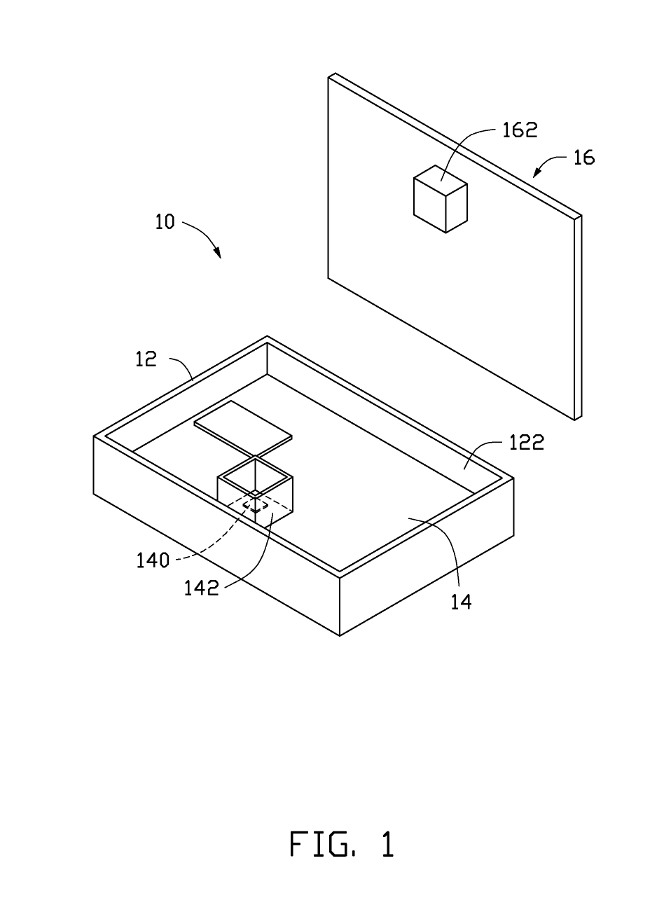

FIG. 1 shows an embodiment of an electronic device 10. The electronic device 10 includes a housing 12, a circuit board 14 received in the housing 12, and a cover 16.

An element 140 and a hollow partition portion 142 receiving the element 140 are mounted on the circuit board 14. The partition portion 142 is made of materials that can not conduct heat.

The housing 12 defines an opening 122 in a side opposite to the element 140.

The cover 16 is capable of conducting heat and includes a block 162 integrally formed on an inner surface of the cover 16.

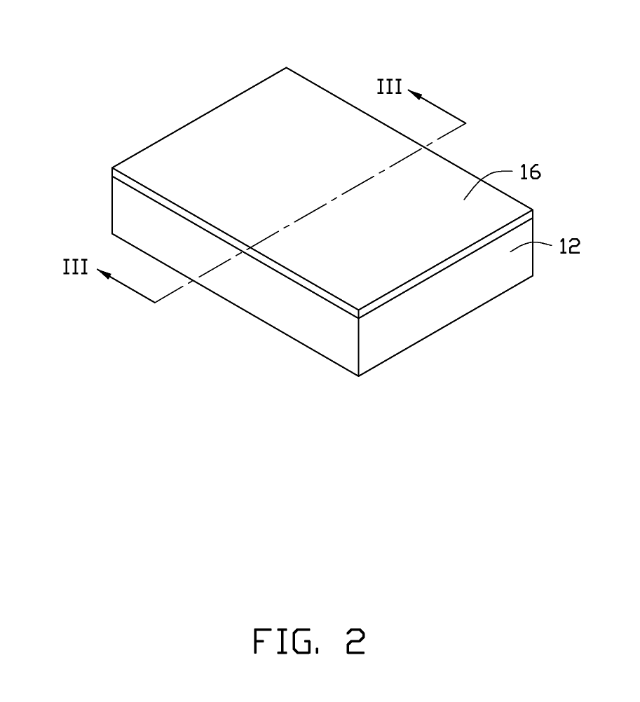

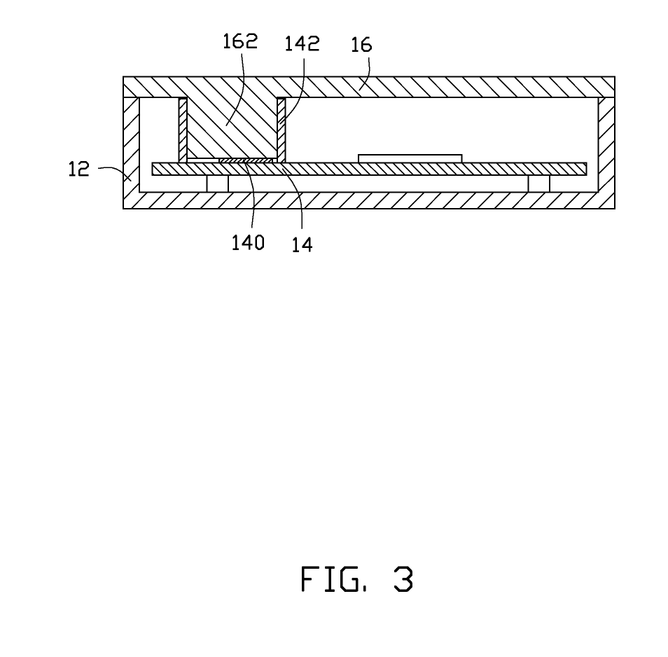

FIGS. 2 and 3 show that in assembly, the cover 16 is mounted to the housing 12 covering the opening 122. The block 162 enters the partition portion 142 and contacts the element 140. A distal end of the partition portion 142 opposite to the circuit board 14 contacts the inner surface of the cover 16.

Because the cover 16 is capable of conducting heat, the heat generated by the element 140 can be conducted to the cover 16 through the block 162, to be dissipated rapidly. Because the element 140 is received in the partition portion 142, heat generated by the element 140 will not diffuse to other inner parts of the housing 12, and the heat generated by the element 140 will not heat up the air inside the electronic device 10.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device, comprising:
a housing defining an opening;
a circuit board mounted in the housing, wherein an element and a hollow partition portion receiving the element are mounted on the circuit board; and
a cover capable of conducting heat and covering the opening; the cover comprising a block formed on an inner surface of the cover, the block entering the partition portion and contacts the element.

2. The electronic device of claim 1, wherein a distal end of the partition portion opposite to the circuit board contacts the inner surface of the cover.
